(19) United States
(12) Patent Application Publication
(10) Pub. No.: US 2013/0043519 A1
(43) Pub. Date: Feb. 21, 2013

(54) SEMICONDUCTOR DEVICES USING SHAPED GATE ELECTRODES

(71) Applicants: Joon-seok Moon, Seoul (KR); Jae-rok Kahng, Seoul (KR); Jin-woo Lee, Yongin-si (KR); Sung-sam Lee, Yongin-si (KR); Dong-soo Woo, Seoul (KR); Kyoung-ho Jung, Suwon-si (KR); Jung-kyu Jung, Goyang-si (KR)

(72) Inventors: Joon-seok Moon, Seoul (KR); Jae-rok Kahng, Seoul (KR); Jin-woo Lee, Yongin-si (KR); Sung-sam Lee, Yongin-si (KR); Dong-soo Woo, Seoul (KR); Kyoung-ho Jung, Suwon-si (KR); Jung-kyu Jung, Goyang-si (KR)

(73) Assignee: Samsung Electronics Co., Ltd.

(21) Appl. No.: 13/589,339

(22) Filed: Aug. 20, 2012

(30) Foreign Application Priority Data
Aug. 19, 2011 (KR) 10-2011-0083046

(51) Int. Cl. H01L 29/78

(52) U.S. Cl. 257/296; 257/330; 257/E29.262

(57) ABSTRACT

A device includes a semiconductor substrate and a gate insulation film lining a trench in an active region of the substrate. A gate electrode pattern is recessed in the trench on the gate insulation film and has an upper surface that has a nonuniform height. A dielectric pattern may be disposed on the gate electrode pattern in the trench.

### CROSS-REFERENCE TO RELATED APPLICATIONS

This application claims the benefit of Korean Patent Application No. 10-2011-0083046, filed on Aug. 19, 2011, in the Korean Intellectual Property Office, the disclosure of which is incorporated herein in its entirety by reference.

### BACKGROUND

The present inventive subject matter relates to semiconductor devices and, more particularly, to semiconductor devices having gate electrode structures.

Modern electronic products are evolving to handle increasingly larger amounts of data while decreasing in size. Accordingly, semiconductor devices used in such electronic products are becoming more highly integrated. However, there are difficulties involved in scaling down device manufacturing processes to produce such high levels of integration.

### SUMMARY

In some embodiments of the inventive subject matter, a device includes a semiconductor substrate and a gate insulation film lining a trench in an active region of the substrate. A gate electrode pattern is recessed in the trench on the gate insulation film and has an upper surface having a nonuniform height. For example, the gate electrode pattern may have a first height at a first point between sidewalls of the trench and a second height different from the first height at a second point more adjacent the sidewalls than the first point. A dielectric pattern may be disposed on the gate electrode pattern in the trench.

In some embodiments, the upper surface of the gate electrode pattern may have a step therein. In some embodiments, such a gate electrode pattern may consist of a single material. In further embodiments, such a gate electrode pattern may include a first pattern comprising a first material and conforming to the gate insulation film and a second pattern comprising a second material disposed on and at least partially surrounded by the first pattern. The first and second patterns may have different resistivities.

In some embodiments, the upper surface of the gate electrode pattern may be concave or convex.

In some embodiments, the device is configured such that a depletion region is formed in the substrate at a level above an upper surface of the gate electrode pattern. The upper surface of the substrate disposed above the depletion region may be electrically connected to a lower electrode of a capacitor.

In some embodiments, the dielectric pattern may include a first dielectric pattern contacting the gate insulation film and the gate electrode pattern and a second dielectric pattern disposed on and at least partially surrounded by the first dielectric pattern. A permittivity of the first dielectric pattern may be different from a permittivity of the second dielectric pattern. In some embodiments, the first dielectric pattern and the second dielectric pattern may include the same material.

In further embodiments, the gate insulation film may be thicker at an upper portion of the trench than at a lower portion of the trench.

In some embodiments of the inventive subject matter, a device includes a substrate and parallel word lines recessed in the substrate. Each word line has an upper surface with a nonuniform height. For example, the upper surface of each word line may have a first height proximate a medial point thereof and a second height different from the first height proximate a lateral edge thereof.

The word lines may be disposed in respective trenches in the substrate and the device may further include respective gate insulation films lining respective ones of the trenches between the word lines and the substrate and respective dielectric patterns disposed on respective ones of the word lines in the trenches.

In some embodiments, the upper surfaces of the word lines may have steps therein.

In some embodiments, each of the word lines consists of a single material.

In further embodiments, the word lines may be disposed in respective trenches in the substrate and each word line may include a first pattern comprising a first material and conforming to the sidewalls of one of the trenches and a second pattern comprising a second material disposed on and at least partially surrounded by the first pattern.

The upper surfaces of the word lines may be concave or convex.

### BRIEF DESCRIPTION OF THE DRAWINGS

Exemplary embodiments of the inventive subject matter will be more clearly understood from the following detailed description taken in conjunction with the accompanying drawings in which:

FIG. 1 is a cross-sectional view of a semiconductor device according to some embodiments of the present inventive subject matter;

FIG. 2 is a cross-sectional view of a semiconductor device according to further embodiments of the present inventive subject matter;

FIG. 3 is a cross-sectional view of a semiconductor device according to further embodiments of the present inventive subject matter;

FIG. 4 is a cross-sectional view of a semiconductor device according to further embodiments of the present inventive subject matter;

FIG. 5 is a cross-sectional view of a semiconductor device according to further embodiments of the present inventive subject matter;

FIG. 6 is a cross-sectional view of a semiconductor device according to further embodiments of the present inventive subject matter;

FIG. 7 is a cross-sectional view of a semiconductor device according to further embodiments of the present inventive subject matter;

FIG. 8 is a cross-sectional view of a semiconductor device according to further embodiments of the present inventive subject matter;

FIGS. 9A-9H are cross-sectional views sequentially illustrating operations for manufacturing a semiconductor device according to some embodiments of the present inventive subject matter;

FIGS. 10A-10I are cross-sectional views sequentially illustrating operations for manufacturing a semiconductor device according to further embodiments of the present inventive subject matter;

FIG. 11 is a graph showing a device operation improvement effect of a semiconductor device according to some embodiments of the present inventive subject matter;

FIG. 12A is a layout of a semiconductor device having a structure according to some embodiments of the present inventive subject matter;

FIG. 12B is a cross-sectional view taken along line 12B-12B′ of FIG. 12A;

FIG. 12C is a cross-sectional view taken along line 12C-12C′ of FIG. 12A;

FIG. 13 is a plan view of a memory module including a semiconductor device according to some embodiments of the present inventive subject matter;

FIG. 14 is a schematic view of a memory card including a semiconductor device according to some embodiments of the present inventive subject matter; and

FIG. 15 is a schematic view of a system including a semiconductor device according to some embodiments of the present inventive subject matter.

### DETAILED DESCRIPTION

Exemplary embodiments are provided to further completely explain the present inventive subject matter to one skilled in the art to which the present inventive subject matter pertains. However, the present inventive subject matter is not limited thereto and it will be understood that various changes in form and details may be made therein without departing from the spirit and scope of the following claims. That is, descriptions on particular structures or functions may be presented merely for explaining exemplary embodiments of the present inventive subject matter.

In the following description, when a layer is described to exist on another layer, the layer may exist directly on the other layer or a third layer may be interposed therebetween. Also, the thickness or size of each layer illustrated in the drawings is exaggerated for convenience of explanation and clarity. Like references indicate like constituent elements in the drawings. As used in the present specification, the term “and/or” includes any one of listed items and all of at least one combination of the items.

The terms used in the present specification are used for explaining a specific exemplary embodiment, not limiting the present inventive subject matter. Thus, the expression of singularity in the present specification includes the expression of plurality unless clearly specified otherwise in context. Also, the terms such as “comprise” and/or “comprising” may be construed to denote a certain characteristic, number, step, operation, constituent element, or a combination thereof, but may not be construed to exclude the existence of or a possibility of addition of one or more other characteristics, numbers, steps, operations, constituent elements, or combinations thereof.

In the present specification, the terms such as “first” and “second” are used herein merely to describe a variety of members, parts, areas, layers, and/or portions, but the constituent elements are not limited by the terms. It is obvious that the members, parts, areas, layers, and/or portions are not limited by the terms. The terms are used only for the purpose of distinguishing one constituent element from another constituent element. Thus, without departing from the right scope of the present inventive subject matter, a first member, part, area, layer, or portion may refer to a second member, part, area, layer, or portion.

Hereinafter, the exemplary embodiments of the present inventive subject matter are described in detail with reference to the accompanying drawings. In the drawings, the illustrated shapes may be modified according to, for example, manufacturing technology and/or tolerance. Thus, the exemplary embodiment of the present inventive subject matter may not be construed to be limited to a particular shape of a part described in the present specification and may include a change in the shape generated during manufacturing, for example.

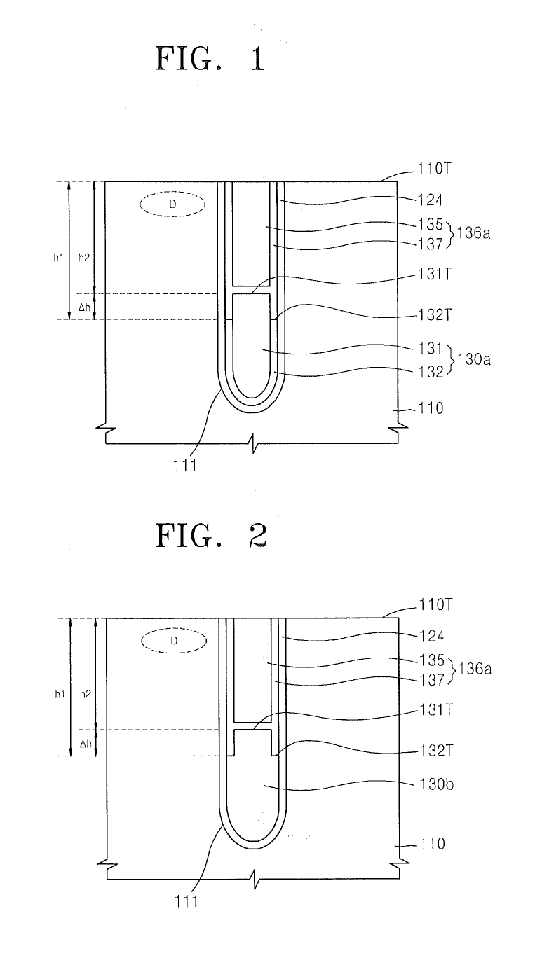

FIG. 1 is a cross-sectional view of a semiconductor device according to some embodiments of the present inventive subject matter. Referring to FIG. 1, a substrate 110 having a trench 111 is provided. The substrate 110 may contain a semiconductor material, for example, IV group semiconductor, III-V group compound semiconductor, or II-VI group oxide semiconductor. For example, the IV group semiconductor may include silicon, germanium, or silicon-germanium. The substrate 110 may be formed of a silicon-on-insulator (SOI) substrate, a gallium-arsenic substrate, a silicon germanium substrate, a ceramic substrate, a crystal substrate, or a glass substrate for display.

In the drawings illustrating cross-sections of the trench 111, a sidewall of the trench 111 is illustrated to be perpendicular to an upper surface 110T of the substrate 110, but the present inventive subject matter is not limited thereto. For example, the sidewall of the trench 111 may be formed at an angle with respect to the upper surface 110T of the substrate 110.

The substrate 110 may include an active region in which impurities are injected. The active region may act as a source/drain region. An N-type impurity source such as PH₃ and AsH₃ or a P-type impurity source such as BF₃ and BCl₃ may be used during an ion injection process to form the active region. For a PN junction, a diffusion of electrons and holes may occur due to a voltage and current applied to a semiconductor device. Accordingly, a depletion region in which the concentration or number of electrons and/or holes is remarkably low may be formed in the active region. The depletion region may be formed in the substrate 110 close to the upper surface 110T and the trench 111 of the substrate 110. The present inventive subject matter is not limited to the above shape and position of a depletion region. The level of the depletion region may be higher than that of a gate electrode pattern 130a.

A gate insulation film 124 is formed on the trench 111 and may include, for example, a silicon oxide film. The gate insulation film 124 may have a uniform thickness along the sidewall of the trench 111. That is, the thickness of the gate insulation film 124 on the upper sidewall of the trench 111 and the thickness of the gate insulation film 124 the lower sidewall of the trench 111 may substantially be the same.

The gate electrode pattern 130a is formed on the gate insulation film 124 and may include a conductive material. The gate electrode pattern 130a may include a first portion 131 and a second portion 132. The first portion 131 of the gate electrode pattern 130a protrudes in a direction toward the upper surface 110T of the substrate 110. For example, the first portion 131 of the gate electrode pattern 130a protrudes above the second portion 132 in a direction toward the upper surface 110T of the substrate 110. The second portion 132 of the gate electrode pattern 130a is arranged on the lateral surface of the first portion 131. The first portion 131 is separated from the gate insulation film 124. The second portion 132 contacts the gate insulation film 124 and may surround the first portion 131.

The gate electrode pattern 130a as shown in FIG. 1 has an upper surface that is nonuniform in height, such that the upper surface of the gate electrode pattern has a different height proximate a medial portion thereof than at portions proximate edges of the gate electrode pattern 130a. In particular, the level of an upper surface 131T of the first portion 131 of the gate electrode pattern 130a is higher than that of an upper surface 132T of the second portion 132 of the gate electrode pattern 130a, that is, the upper surface 131T of the first portion 131 is located at a depth h2 from the upper surface 110T of the substrate 110. An upper surface 132T of the second portion 132 is located at a depth h1 from the upper surface 110T of the substrate 110. The depth h1 is larger than the depth h2. Thus, the upper surface 131T of the first portion 131 and the upper surface 132T of the second portion 132 form a step with a height Δh. The first portion 131 includes a protruding portion that protrudes above the upper surface 132T of the second portion 132 in a direction toward the upper surface 110T of the substrate 110. The height of the protruding portion corresponds to height Δh of the step. In other words, the gate electrode pattern 130a has a shape that the lateral portion contacting the gate insulation film 124 is recessed by the step height Δh.

The first portion 131 and the second portion 132 may be formed of different materials. The resistivity of the material forming the first portion 131 may be lower than that of the material forming the second portion 132.

The first portion 131 may be formed of a conductive material, such as metal, a metal alloy, a metal nitride, or a metal silicide. For example, the first portion 131 may be formed of at least one of TiN, TiSiN, WN, TaN, Ta, Ti, Ru, W, Al, and polysilicon. The first portion 131 may be formed by, for example, a physical vapour deposition (PVD) process, a chemical vapour deposition (CVD) process and/or an atomic layer deposition (ALD) process. The second portion 132 may be formed of metal, a metal alloy, a metal nitride, or a metal silicide. For example, the second portion 132 may be formed of at least one of TiN, TiSiN, WN, TaN, Ta, Ti, Ru, W, Al, and polysilicon. The second portion 132 may be formed by, for example, a PVD process, a CVD process and/or an ALD process. For example, the first portion 131 may be formed of tungsten (W), whereas the second portion 132 may be formed of titanium nitride (TiN).

In the structure in which the gate electrode pattern 130a is fully buried in the trench 111 of the active region according to the present inventive subject matter, since a bit line and a word line of a semiconductor device do not overlap with each other, bit line loading capacitance due to the overlap between the word line and the bit line may be reduced. However, when a metal gate having a low resistance is used to reduce resistance of a word line, gate induced drain leakage (GIDL) may occur in an area where the metal gate and the source/drain region overlap, potentially causing data retention time to be markedly reduced. In particular, when the area where the metal gate and the source/drain region overlap is electrically connected to a lower electrode of a capacitor, the GIDL may become severe. It seems that a large work function of the metal gate is a major reason for the above problem.

In the illustrated embodiments, the level of the upper surface 132T of the second portion 132 may be lower than that of the depletion region D. Furthermore, the level of the upper surface 131T of the first portion 131 may be lower than that of the depletion region D.

Referring to FIG. 1, a dielectric pattern 136a is formed on the gate electrode pattern 130a to fill the trench 111. That is, the dielectric pattern 136a is formed after the gate insulation film 124 and the gate electrode pattern 130a are formed in the trench 111, thereby filling the space in the trench 111.

A distance between the depletion region D and a portion of the gate electrode pattern 130a directly contacting the gate insulation film 124 may be an important factor in the GIDL. As a distance between the upper surface 132T of the second portion 132 and the depletion region D increases, that is, as the depth h1 in FIG. 1 increases, the GIDL may decrease. However, the resistance of a word line may increase as the depth h1 increases. In order to reduce GIDL without increasing the resistance of a word line, the first portion 131 may be separated from the gate insulation film 124 and protrude higher than the second portion 132. Thus, as the height of the upper surface 131T of the first portion 131 protruding above the upper surface 132T of the second portion 132 increases, that is, as the depth h2 of FIG. 1 decreases, the resistance of a word line may decrease.

The first portion 131 may contribute to the reduction of the resistance of a word line, whereas the second portion 132 may contribute to the reduction of GIDL. Accordingly, the gate electrode pattern 130a in the illustrated embodiments may realize both the reduction of the resistance of a word line and the reduction of the GIDL.

The dielectric pattern 136a may fill the trench 111 surrounding a part of the first portion 131 protruding above the upper surface 132T of the second portion 132, that is, a part of the first portion 131 corresponding to the step height Δh. The dielectric pattern 136a may be understood as a capping layer.

The dielectric pattern 136a may include a first dielectric pattern 137 that contacts the gate insulation film 124 and the gate electrode pattern 130a. Furthermore, the dielectric pattern 136a may include a second dielectric pattern 135 arranged on the first dielectric pattern 137. The first dielectric pattern 137 and the second dielectric pattern 135 may be exposed on the upper surface 110T of the substrate 110. The first dielectric pattern 137 may have a shape of surrounding the second dielectric pattern 135. In addition, the first dielectric pattern 137 may have a shape of surrounding the protruding portion of the first portion 131 that protrudes above the upper surface 132T of the second portion 132. The first dielectric pattern 137 may contact the upper surface 132T of the second portion 132 and the gate insulation film 124. Since the first dielectric pattern 137 is interposed between the second dielectric pattern 135 and the gate insulation film 124, the second dielectric pattern 135 does not contact the gate insulation film 124.

The first dielectric pattern 137 and the second dielectric pattern 135 may be formed of different materials. A permittivity of the first dielectric pattern 137 may be lower than that of the second dielectric pattern 135. For example, the first dielectric pattern 137 may be formed of an oxide, such as silicon oxide, whereas the second dielectric pattern 135 may be formed of a nitride, such as silicon nitride. In addition the first and second dielectric patterns 137 and 135 may be formed of high temperature oxide (HTO), medium temperature oxide (MTO), plasma enhanced tetraethyl orthosilicate (PE-TEOS), spin on glass (SOG), undoped silicate glass (USG), high density plasma (HDP) CVD oxide, Tonen SilaZene (TOSZ), or a combination thereof.

As a result, the dielectric pattern 136a including the first dielectric pattern 137 and the second dielectric pattern 135 having the above-described physical properties and shapes reduces an electric field generated between the gate electrode pattern 130a and the depletion region D, thereby effectively contributing to the reduction of the GIDL.

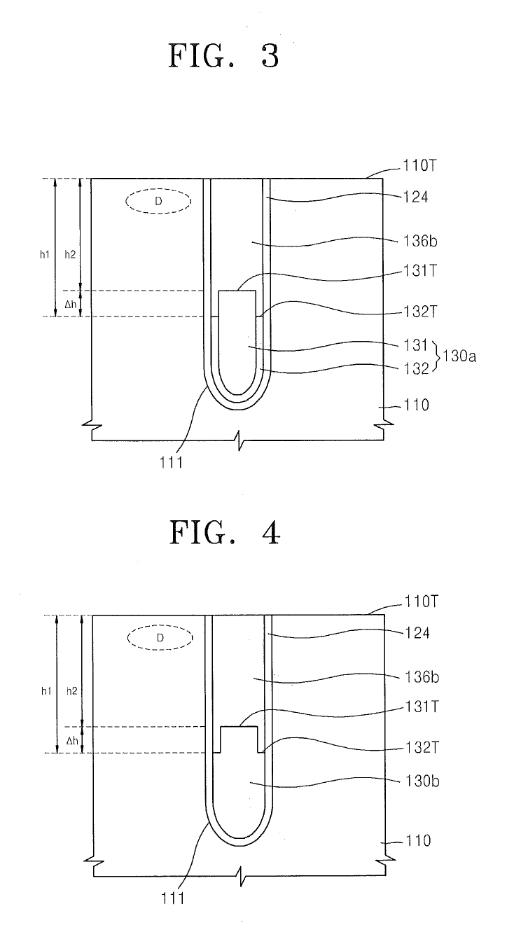

FIG. 2 is a cross-sectional view of a semiconductor device according to further embodiments of the present inventive subject matter. Since the substrate 110, the depletion region D, and the dielectric pattern 136a are the same as those described above with reference to FIG. 1, repeated descriptions thereof will be omitted.

Referring to FIG. 2, a gate electrode pattern 130b is equivalent to a case in which the first and second portions 131 and 132 forming the gate electrode pattern 130a are formed of the same material. The gate electrode pattern 130b may be formed of a conductive material, such as metal, a metal alloy, a metal nitride and/or a metal silicide. For example, the gate electrode pattern 130b may be formed of at least one of TiN, TiSiN, WN, TaN, Ta, Ti, Ru, W, Al, and polysilicon.

An upper surface of the gate electrode pattern 130b has a step of height Δh. The upper surface of the gate electrode pattern 130b that is recessed is adjacent to the gate insulation film 124. In other words, a part of the gate electrode pattern 130b that protrudes by the step height Δh is separated from the gate insulation film 124 without contact therewith. Although the gate electrode pattern 130b is formed of a single material, for convenience of explanation, an upper surface of the gate electrode pattern 130b protruding by Ah is referred to as an upper surface 131T of the first portion and an upper surface of the gate electrode pattern 130b that is recessed by Ah is referred to as the upper surface 132T of the second portion to correspond to the gate electrode pattern 130a of FIG. 1.

The distance between the depletion region D and the portion of the gate electrode pattern 130b directly contacting the gate insulation film 124 may be an important factor in the GIDL. As the distance between the depletion region D and the upper surface 132T of the second portion increases, that is, the depth h1 of FIG. 2 increases, the GIDL may decrease. The resistance of a word line may decrease as the height of the upper surface 131T of the first portion protruding above the upper surface 132T of the second portion increases, that is, the depth h2 of FIG. 2 decreases.

The upper surface 131T of the first portion that protrudes may contribute to the reduction of the resistance of a word line, whereas the upper surface 132T of the second portion that is recessed may contribute to the reduction of the GIDL. Thus, the gate electrode pattern 130b in the illustrated embodiments may simultaneously realize the reduction of the resistance of a word line and the reduction of the GIDL.

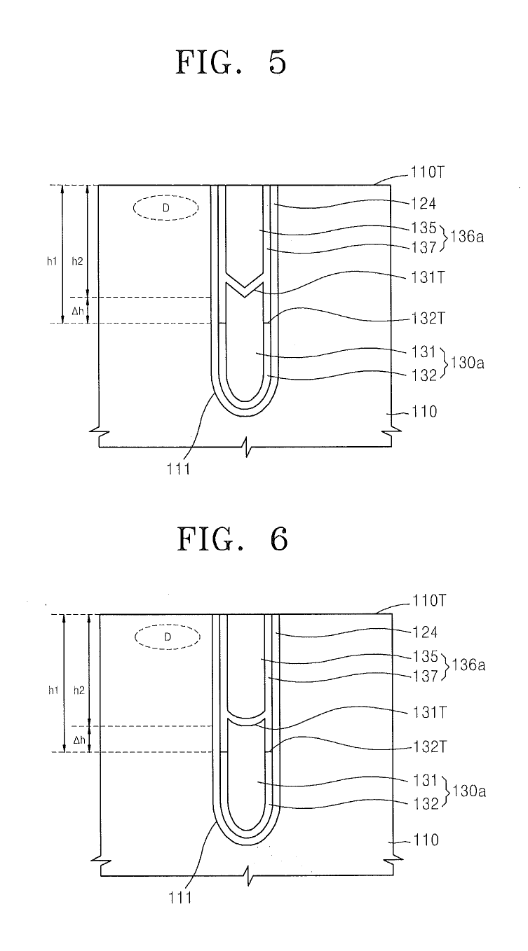

FIG. 3 is a cross-sectional view of a semiconductor device according to further embodiments of the present inventive subject matter. Since the substrate 110, the depletion region D, and the dielectric pattern 136a are the same as those described above with reference to FIG. 1, repeated descriptions thereof will be omitted.

Referring to FIG. 3, a dielectric pattern 136b is substantially equivalent in shape to a combination of the first dielectric pattern 137 and the second dielectric pattern 135 of the dielectric pattern 136a of FIG. 1. The dielectric pattern 136b may be formed of a predetermined material in an integrated pattern. The dielectric pattern 136b may include an electric insulation material. For example, the dielectric pattern 136b may include an oxide, such as a silicon oxide, and/or a nitride, such as a silicon nitride. However, the material forming the dielectric pattern 136b is not limited thereto and the dielectric pattern 136b may be formed of any of a variety of different dielectric materials known in the technical field. For example, the dielectric pattern 136b may include a low dielectric material having a dielectric constant of 3 or lower.

The dielectric pattern 136b fills the space in the trench 111 after the gate insulation film 124 and the gate electrode pattern 130a are formed in the trench 111. The dielectric pattern 136b covers the upper surface 131T of the first portion 131 and the upper surface 132T of the second portion 132.

The distance between the depletion region D and the portion of the gate electrode pattern 130a directly contacting the gate insulation film 124 may be an important factor in the GIDL. As the distance between the depletion region D and the upper surface 132T of the second portion 132 increases, that is, the depth h1 of FIG. 3 increases, the GIDL may decrease. However, it may be a problem that the resistance of a word line increases as the depth h1 increases. To address this problem, the first portion 131 may be separated from the gate insulation film 124 and protrude above the second portion 132. Thus, the resistance of a word line may decreases as the height of the upper surface 131T of the first portion 131 protruding above the upper surface 132T of the second portion 132 increases, that is, as the depth h2 of FIG. 3 decreases.

The first portion 131 may contribute to the reduction of the resistance of a word line, whereas the second portion 132 may contribute to the reduction of the GIDL. The gate electrode pattern 130a according to the illustrated embodiments may simultaneously realize the reduction of the resistance of a word line and the reduction of the GIDL.

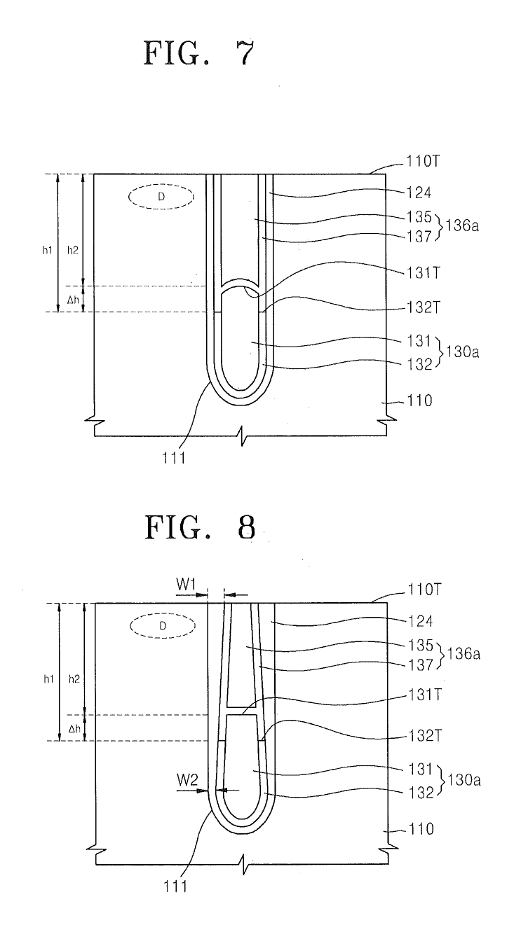

FIG. 4 is a cross-sectional view of a semiconductor device according to further embodiments of the present inventive subject matter. Since the substrate 110, the depletion region D, the gate electrode pattern 130b, and the dielectric pattern 136a are the same as those described above with reference to FIGS. 1-3, repeated descriptions thereof will be omitted.

The gate electrode pattern 130b corresponds to the gate electrode pattern 130b of FIG. 2. The dielectric pattern 136b corresponds to the dielectric pattern 136b of FIG. 3. The gate electrode pattern 130b and the dielectric pattern 136b are respectively formed in an integrated pattern so that the manufacturing process of a semiconductor device may be simplified.

The distance between the depletion region D and a portion of the gate electrode pattern 130b directly contacting the gate insulation film 124 may be an important factor in the GIDL. As the distance between the upper surface 132T of the second portion and the depletion region D increases, that is, as the depth h1 of FIG. 4 increases, the GIDL decreases. However, it is a problem that, as the depth h1 increases, the resistance of a word line may increase. As the height of the upper surface 131T of the first portion above the upper surface 132T of the second portion increases, that is, as the depth h2 of FIG. 4 decreases, the resistance of a word line may decrease.

The upper surface 131T that protrudes may contribute to the reduction of the resistance of a word line, whereas the upper surface 132T that is recessed may contribute to the reduction of the GIDL. Thus, the gate electrode pattern 130b according to the illustrated embodiments may simultaneously realize the reduction of the resistance of a word line and the reduction of the GIDL.

In the above-described embodiments, the upper surface of the gate electrode pattern 130a or 130b has step of height Δh and the shape of the upper surface 131T of the first portion 131 is generally flat. However, according to some embodiments of the present inventive subject matter, the upper surface 131T of the first portion 131 of the gate electrode pattern 130a or 130b may have any of a variety of other shapes.

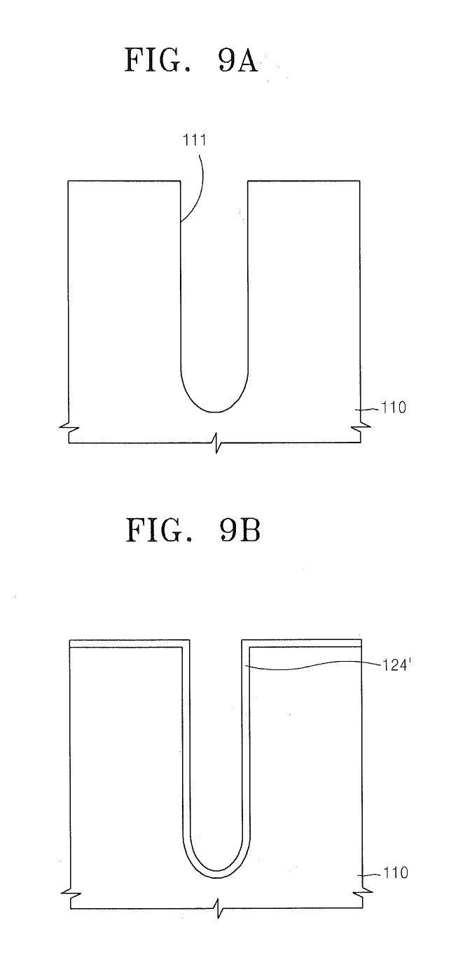

FIGS. 5-7 illustrate various shapes of the upper surface 131T of the first portion 131 of the gate electrode pattern 130a. Although the structure of the substrate 110, the gate insulation film 124, the gate electrode pattern 130a, and the dielectric pattern 136a of FIG. 1 is illustrated in FIGS. 5-7, the present inventive subject matter is not limited thereto and may be applied to a semiconductor device having a combination of any of the substrate, the gate insulation film, the gate electrode pattern, and the dielectric pattern described in the present specification.

FIG. 5 is a cross-sectional view of a semiconductor device according to further embodiments of the present inventive subject matter. Referring to FIG. 5, the upper surface 131T of the first portion 131 of the gate electrode pattern 130a may have an angled concave shape, for example, an M shape, in which the inner side of the upper surface 131T is recessed from the outer side thereof. The first portion 131 of the gate electrode pattern 130a may include tungsten, and a seam may be formed in the inner side of the first portion 131 and the inner side may be recessed.

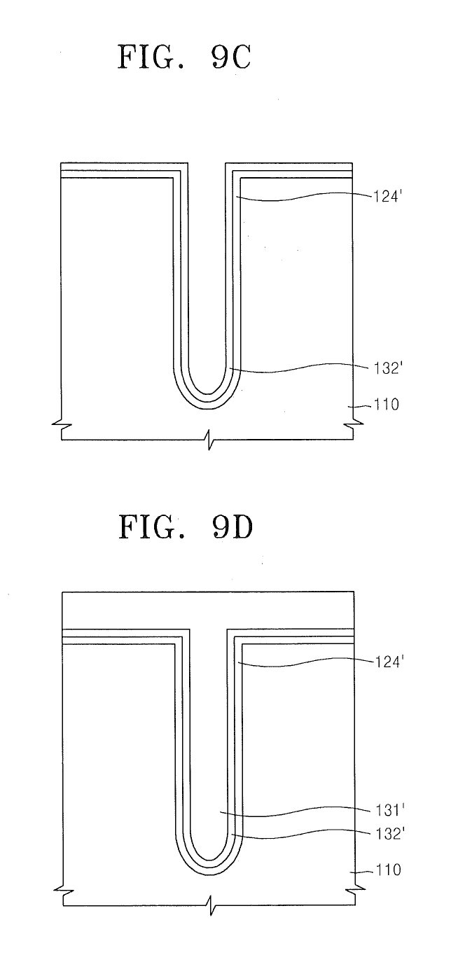

FIG. 6 is a cross-sectional view of a semiconductor device according to further embodiments of the present inventive subject matter. Referring to FIG. 6, the upper surface 131T of the first portion 131 of the gate electrode pattern 130a may have a rounded concave shape in which the inner side of the upper surface 131T is recessed from the outer side thereof.

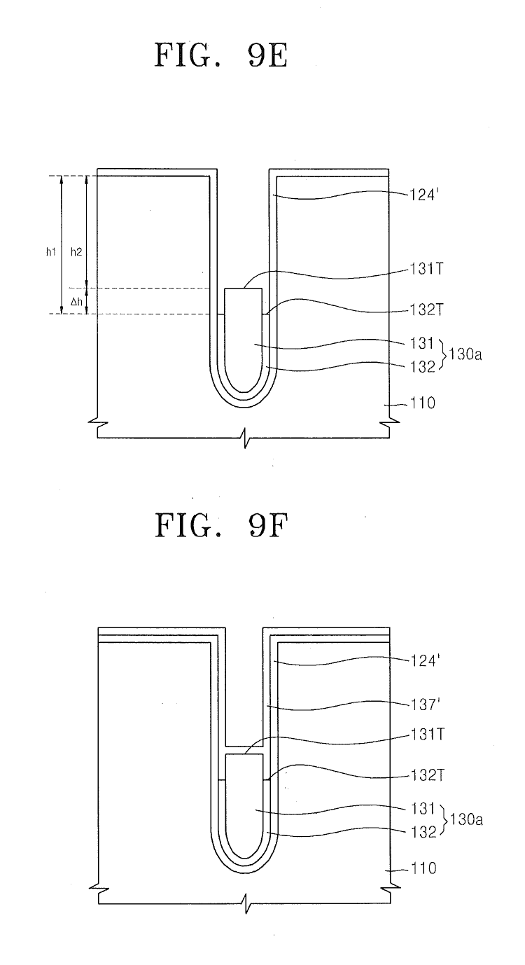

FIG. 7 is a cross-sectional view of a semiconductor device according to further embodiments of the present inventive subject matter. Referring to FIG. 7, the upper surface 131T of the first portion 131 of the gate electrode pattern 130a may have a rounded convex shape in which the inner side of the upper surface 131T protrudes above the outer side thereof.

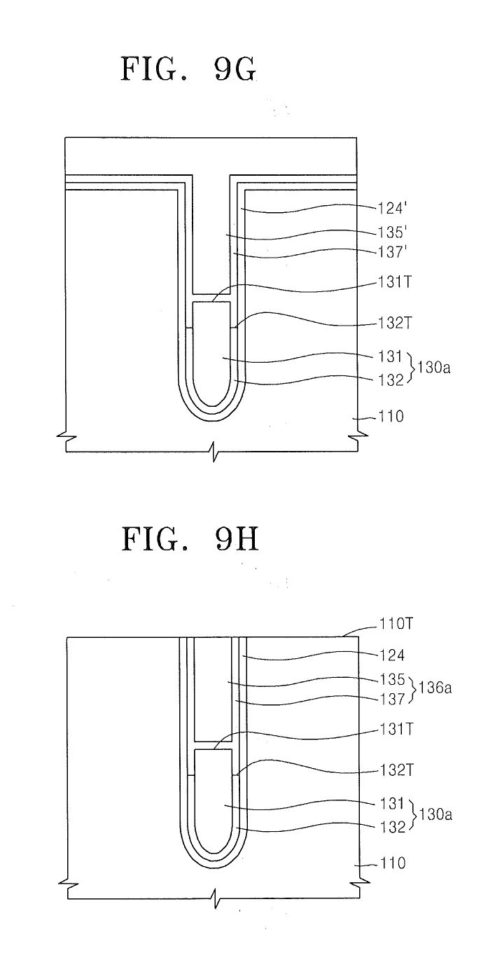

FIG. 8 is a cross-sectional view of a semiconductor device according to further embodiments of the present inventive subject matter. Since the substrate 110, the depletion region D, the gate electrode pattern 130a, and the dielectric pattern 136a are the same as those described above with reference to FIG. 1, repeated descriptions thereof will be omitted. Although FIG. 8 illustrates the structure of the substrate 110, the depletion region D, the gate electrode pattern 130a, and the dielectric pattern 136a, the present inventive subject matter is not limited thereto and may be applied to a semiconductor device having a combination of any of the substrate, the depletion region, the gate electrode pattern, and the dielectric pattern described in the present specification.

The gate insulation film 124 may be formed such that a thickness W1 in an upper portion of the trench 111 is thicker than a thickness W2 in a lower portion of the trench 111, As described above, since the region where the GIDL occurs includes the region between the gate electrode pattern 130a and the depletion region D, forming the gate insulation film 124 to have a relatively greater thickness in the upper portion of the trench 111 may be advantageous for the reduction of the GIDL.

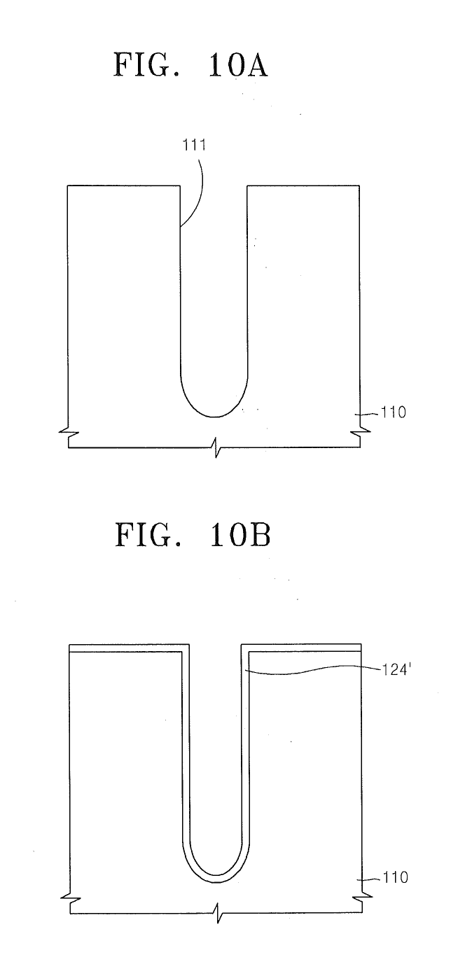

FIGS. 9A-9H are cross-sectional views sequentially illustrating operations for manufacturing the semiconductor device of FIG. 1. Since the structures and properties of the substrate 110, the depletion region D, the gate electrode pattern 130a, and the dielectric pattern 136a are the same as those described above with reference to FIG. 1, repeated descriptions thereof will be omitted.

Referring to FIG. 9A, the trench 111 is formed in the substrate 110 by performing anisotropic dry etching on the substrate 110 using a hard mask pattern formed on the substrate 110 as an etch mask.

Referring to FIGS. 9B and 9C, a gate insulation film 124′ and a second portion 132′ of a gate electrode pattern (130a) are sequentially formed on the substrate 110.

Referring to FIG. 9D, a first portion 131′ of the gate electrode pattern (130a) is formed on the second portion 132′ of the gate electrode pattern to fill all of the remaining space of the trench 111.

Referring to FIG. 9E, the first portion 131 and the second portion 132 of the gate electrode pattern 130a are formed by respectively etching the first portion 131′ and the second portion 132′ of the gate electrode pattern to predetermined depths. The second portion 132′ of the gate electrode pattern may be etched deeper than the first portion 131′ of the gate electrode pattern by adjusting the conditions of an etch process, for example, an etchback process. Accordingly, the upper surface 131T of the first portion 131 is located at the depth h2 from the upper surface of the substrate 110, whereas the upper surface 132T of the second portion 132 is located at the depth h1 from the upper surface of the substrate 110. The depth h1 is greater than the depth h2.

Referring to FIGS. 9F and 9G, a first dielectric layer 137′ is formed on the gate insulation film 124′ and the gate electrode pattern 130a and a second dielectric layer 135′ is formed on the first dielectric layer 137′, thereby completely filling the empty space of the trench 111.

Referring to FIG. 9H, the second dielectric layer 135′, the first dielectric layer 137′, and the gate insulation film 124′ are etched to expose an upper surface 110T of the substrate 110. Accordingly, the second dielectric pattern 135, the first dielectric pattern 137, and the gate insulation film 124 of the semiconductor device of FIG. 1 are formed.

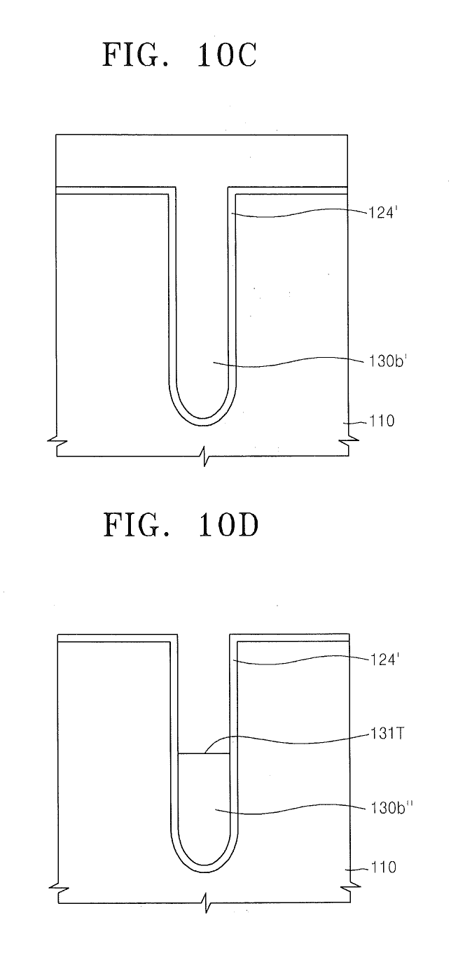

FIGS. 10A-10I are cross-sectional views sequentially illustrating operations for manufacturing the semiconductor device of FIG. 2. Since the structures and properties of the substrate 110, the depletion region D, the gate electrode pattern 130b, and the dielectric pattern 136a are the same as those described above with reference to FIG. 2, repeated descriptions thereof will be omitted.

Referring to FIG. 10A, the trench 111 is formed in the substrate 110 by performing anisotropic dry etching on the substrate 110 using a hard mask pattern formed on the substrate 110 as an etch mask.

Referring to FIGS. 10B and 10C, a gate insulation film 124′ and a gate electrode layer 130b′ are sequentially formed on the substrate 110. The gate electrode layer 130b′ is formed to fill all the empty space of the trench 111.

Referring to FIG. 10D, a remaining portion 130b″ of a gate electrode layer (130b′) existing in the trench 111 is formed by etching the gate electrode layer 130b′ for a predetermined time. The upper surface 131T of the remaining portion 130b″ of the gate electrode layer (130b′) may be a flat surface without a step.

Referring to FIG. 10E, a first material layer 125 and a second material layer 126 are sequentially formed on the gate insulation film 124′ and the remaining portion 130b″ of the gate electrode layer. The first material layer 125 and the second material layer 126 may be formed of materials having high etch selectivities with respect to each other. The second material layer 126 may be formed of the same material as the gate insulation film 124′. For example, the first material layer 125 may be formed of a nitride film, whereas the second material layer 126 may be formed of an oxide film.

Referring to FIG. 10F, the first material layer 125 is selectively etched to expose the upper surface 131T of the remaining portion 130b″ of the gate electrode pattern (130b′). Then, the exposed remaining portion 130b″ of the gate electrode pattern (130b′) is etched by the step height Δh to form the gate electrode pattern 130b. Thus, an upper portion of the gate electrode pattern 130b has a step that is recessed a distance Δh. The upper portion of the gate electrode pattern 130b that is recessed is adjacent to the gate insulation film 124. Thus, in another point of view, the portion of the gate electrode pattern 130b that protrudes as much as the step of height Δh is separated from the gate insulation film 124 without contacting the gate insulation film 124.

Referring to FIGS. 10G and 10H, a first dielectric layer 137′ is formed on the gate insulation film 124′ and the gate electrode pattern 130b and a second dielectric layer 135′ is formed on the first dielectric layer 137′, thereby completely filling the empty space of the trench 111. For example, the first dielectric layer 137′ may be formed of an oxide such as a silicon oxide, whereas the second dielectric layer 135′ may be formed of a nitride such as a silicon nitride.

Referring to FIG. 10I, the second dielectric layer 135′, the first dielectric layer 137′, and the gate insulation film 124′ are etched to expose an upper surface 110T of the substrate 110. Accordingly, the second dielectric pattern 135, the first dielectric pattern 137, and the gate insulation film 124 of the semiconductor device of FIG. 2 are formed.

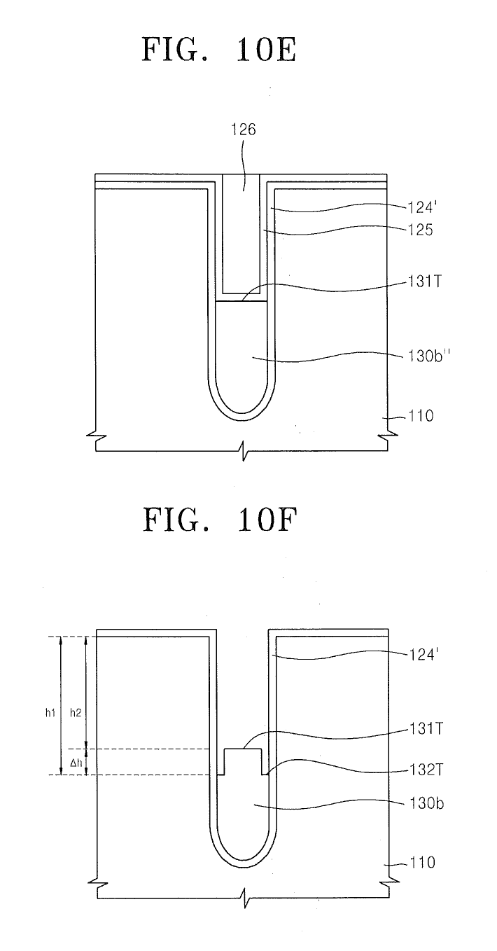

FIG. 11 is a graph showing a device operation improvement effect of a semiconductor device according to some embodiments of the present inventive subject matter. Referring to FIG. 11, there is a difference in a threshold voltage related to row fail with respect to semiconductor devices of Group A and semiconductor devices of Group B. The semiconductor devices of Group B are configured like the semiconductor devices of FIG. 1. In the semiconductor devices of Group A, unlike those illustrated in FIG. 1, the upper surface of the gate electrode pattern is flat without being recessed. The gate electrode pattern includes an integrated structure in which the first and second portions are formed of the same material.

The semiconductor devices of Group A show a very large variation of about 52 mV in the threshold voltage, whereas the semiconductor devices of Group B show a very small difference of about 0 mV in the threshold voltage. Thus, in the semiconductor device according to the present inventive subject matter, the difference in the threshold voltage related to the row fail is very small and thus device operation may be improved

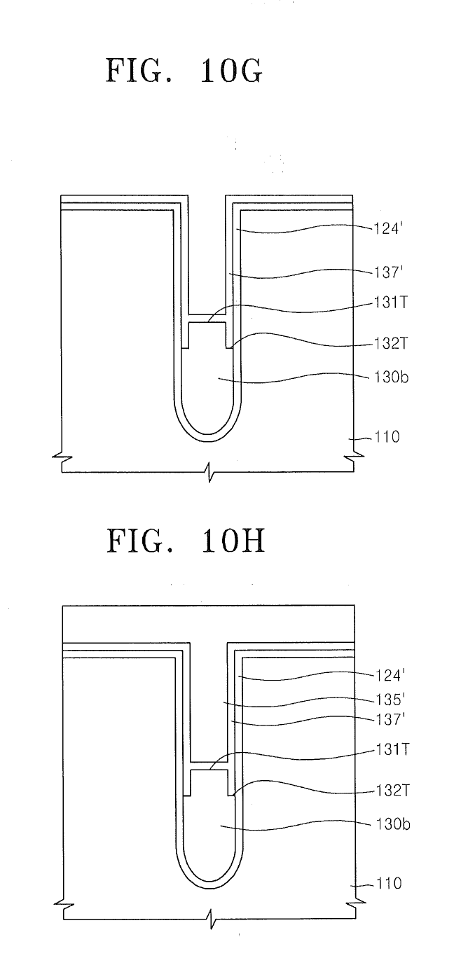

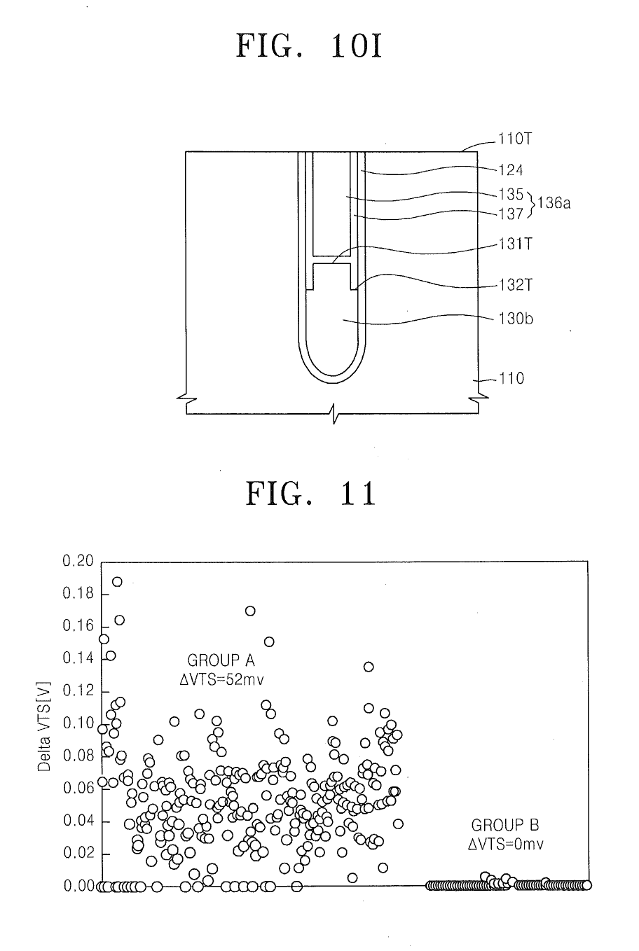

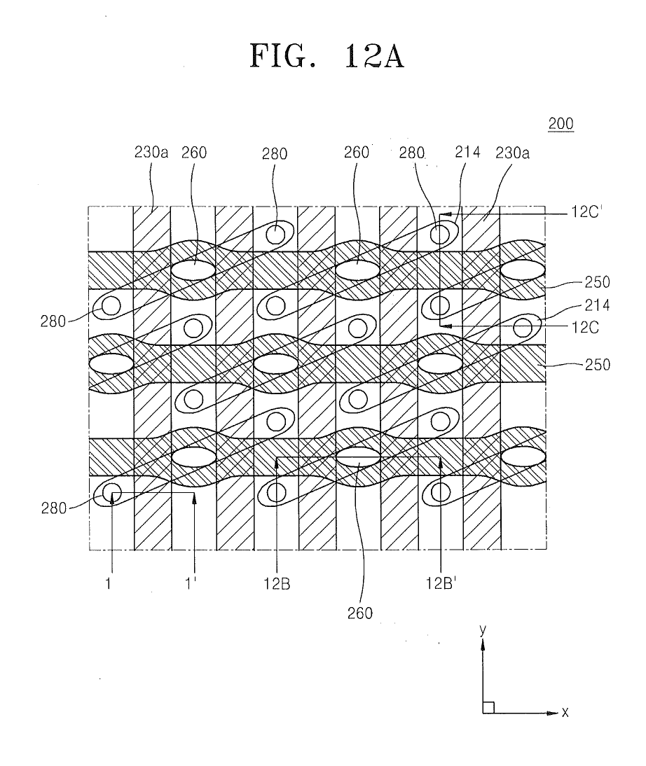

FIG. 12A is a layout of a semiconductor device 200 having a structure according to some embodiments of the present inventive subject matter. FIG. 12B is a cross-sectional view taken along line 12B-12B′ of FIG. 12A. FIG. 12C is a cross-sectional view taken along line 12C-12C′ of FIG. 12A.

The structure of the semiconductor device 200 illustrated in FIGS. 12A-12C may be applied to, for example, a cell array area of a dynamic random access memory (DRAM), in particular, to a cell array area where a DRAM memory cell having a unit cell size of 6 F² is formed. However, the present inventive subject matter is not limited thereto. 1 F signifies the minimum feature size.

Referring to FIGS. 12A-12C, the semiconductor device 200 includes a device separation film 216 that defines a plurality of active regions 214 on a substrate 210. The substrate 210 may be formed of a semiconductor such as Si.

A plurality of gate electrode patterns 230a having an upper surface lower than an upper surface 210T of each of the active regions 214 extend in the substrate 210 in a first direction that is a direction y in FIG. 12A and parallel to a main surface extension direction of the substrate 210. Since each of the gate electrode patterns 230a corresponds to the gate electrode pattern 130a of FIG. 1, repeated description thereof will be omitted.

The upper surfaces of the gate electrode patterns 230a are covered by a dielectric pattern 236a. The dielectric pattern 236a may correspond to the dielectric pattern 136a of FIG. 1, and a detailed description thereof will be omitted.

A gate insulation film 224 is formed between the gate electrode patterns 230a and the active regions 214.

An impurity region 218 that may act as a source/drain region is formed in each of the active regions 214. The impurity region 218 extends to a depth of the inside of the substrate 210 from the upper surface 210T of each of the active regions 214.

A plurality of bit lines 250 extend on the gate electrode patterns 230a in a second direction that is a direction x in FIG. 12A and perpendicular to the first direction. The bit lines 250 may have a structure in which a first bit line conductive pattern 250A and a second bit line conductive pattern 250B that are formed of different materials are sequentially deposited. However, the present inventive subject matter is not limited thereto.

The semiconductor device 200 has a structure in which two gate electrode patterns 230a for each of the active regions 214 extend in the direction y. A direct contact 260 is formed for each of the active regions 214 between the two gate electrode patterns 230a passing through the active regions 214. The direct contact 260 passes through the first bit line conductive pattern 250A that forms the bit lines 250 in a contact hole 250H that penetrates the first bit line conductive pattern 250A. The direct contact 260 is electrically connected to the impurity region 218 formed in the active region 214. The bit lines 250 are electrically connected to the impurity region 218 of the active region 214 via the direct contact 260.

The direction contact 260 has a structure including a first contact conductive layer 262 and a second contact conductive layer 264, which may be sequentially deposited. The first contact conductive layer 262 directly contacts the first bit line conductive pattern 250A and the impurity region 218 of the active region 214 in the contact hole 250H formed in the first bit line conductive pattern 250A. The second contact conductive layer 264 fills the remaining space of the contact hole 250H on the first contact conductive layer 262.

A buried contact 280 is formed at both sides of the two gate electrode patterns 230a passing through the active region 214 for each active region 214. The buried contact 280 is electrically connected to the impurity region 218 of the active region 214. The buried contact 280 is disposed between a lower electrode of a capacitor and the impurity region 218 and electrically connects the lower electrode and the impurity region 218. In particular, as illustrated in FIG. 12C, the buried contact 280 may have a shape of a direct buried contact that is directly connected to the impurity region 218 of the active region 214. Since the depletion region D of FIG. 12D corresponds to the depletion region D of FIG. 1, repeated description thereof will be omitted.

The buried contact 280 has a structure including a third contact conductive layer 282 and a fourth contact conductive layer 284, which may be sequentially deposited. The third contact conductive layer 282 is formed in the contact hole 270H formed in an interlayer insulation film 270 on the substrate 210 and directly contacts the impurity region 218 of the active region 214. An insulation spacer 272 is interposed between the interlayer insulation film 270 and the third contact conductive layer 282. The fourth contact conductive layer 284 fills the remaining space of the contact hole 270H on the third contact conductive layer 282.

Although the structure of the semiconductor device 200 of FIGS. 12A-12C includes the substrate 110, the depletion region D, the gate electrode pattern 130a, and the dielectric pattern 136a of FIG. 1, the present inventive subject matter is not limited thereto and may be applied to a semiconductor device having a combination of any of the substrate, the depletion region, the gate electrode pattern, and the dielectric pattern described in the present specification.

As described above, the distance between the depletion region D and the portion of the gate electrode pattern 230a directly contacting the gate insulation film 224 may be an important factor in the GIDL. Thus, as the distance between the depletion region D and an upper surface 232T of a second portion 232 increases, the GIDL may decrease. However, as the distance increases, the resistance of a word line may increase. To address the matter, a first portion 231 is formed to be separated from the gate insulation film 224 and to protrude above the second portion 232. Thus, as the height of the upper surface 231T of the first portion 231 protrudes above the upper surface 232T of the second portion 232 increases, the resistance of a word line may decrease.

The first portion 231 may contribute to the reduction of the resistance of a word line, whereas the second portion 232 may contribute to the reduction of the GIDL. Accordingly, the gate electrode pattern 230a according to the illustrated embodiments may simultaneously realize the reduction of the resistance of a word line and the reduction of the GIDL.

In some embodiments, the reduction of the resistance of a word line and the reduction of the GIDL may be simultaneously realized. In some embodiments, a protruding portion of the gate electrode pattern reduces the resistance of a word line, whereas the recessed portion of the gate electrode pattern reduces the GIDL. Two dielectric patterns having different permittivities may form a capping layer, which may additionally reduce GIDL.

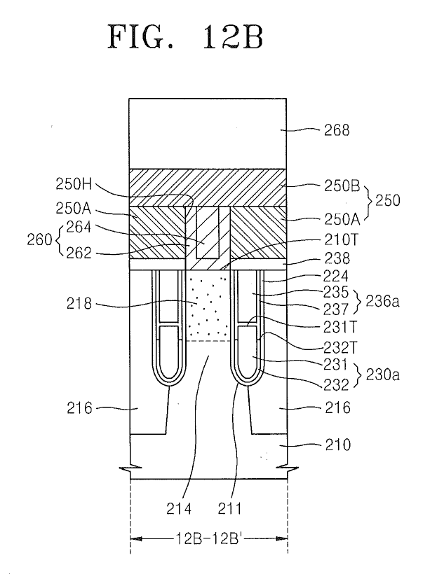

FIG. 13 is a plan view of a memory module 300 including a semiconductor device according to some embodiments of the present inventive subject matter. Referring to FIG. 13, the memory module 300 includes a printed circuit board 310 and a plurality of semiconductor packages 320. The semiconductor packages 320 may include the semiconductor devices according to some embodiments of the present inventive subject matter. In particular, the semiconductor packages 320 may include semiconductor devices as described with reference to FIGS. 1-8, 9A-10I, and 12A-12C.

The memory module 300 according to the illustrated embodiments may be a single in-line memory module (SIMM) in which the semiconductor packages 320 are mounted only on one side of the printed circuit board 310 or a dual in-lined memory module (DIMM) in which the semiconductor packages 320 are mounted on both sides of the printed circuit board 310. Also, the memory module 300 according to the illustrated embodiments may be a fully buffered DIMM (FBDIMM) having an advanced memory buffer (AMB) for providing each of the semiconductor packages 320 with external signals.

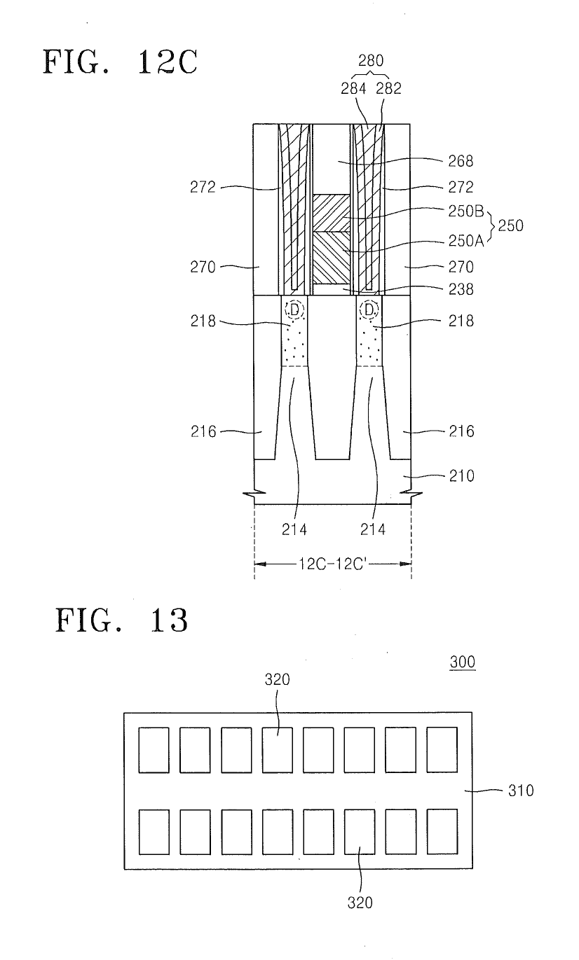

FIG. 14 is a schematic view of a memory card 400 including a semiconductor device according to some embodiments of the present inventive subject matter. Referring to FIG. 14, the memory card 400 includes a controller 410 and a memory 420 which exchange electric signals. For example, when the controller 410 issues a command, the memory 420 may transmit data.

The memory 420 may include the semiconductor devices according to the above-described embodiments. In particular, the memory 420 may include the semiconductor devices described with reference to FIGS. 1-8, 9A-10I, and 12A-12C. The memory card 400 may be one of a variety of memory cards such as a memory stick card, a smart media (SM) card, a secure digital (SD) card, a mini-secure digital (mini SD) card, a multimedia card (MMC).

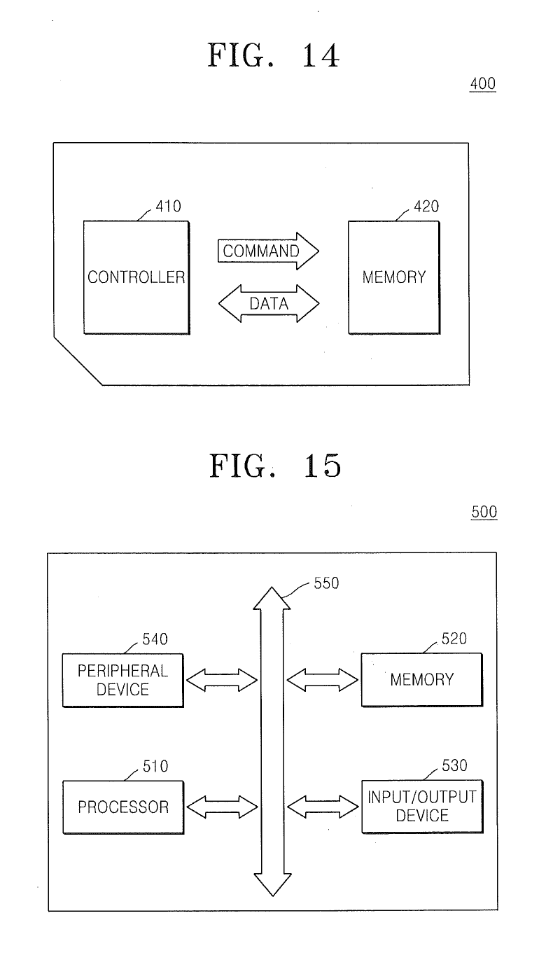

FIG. 15 is a schematic view of a system 500 including a semiconductor device according to some embodiments of the present inventive subject matter. Referring to FIG. 15, the system 500 includes a processor 510, an input/output device 530, and a memory 520 which may perform data communication using a bus 550. The memory 520 of the system 500 may include a random access memory (RAM) and a read only memory (ROM). Also, the system 500 may include a peripheral device 540 such as a floppy disk drive or a compact disk (CD) ROM drive.

The memory 520 may include semiconductor devices according to the above-described embodiments. For example, the memory 520 may include the semiconductor devices described with reference to FIGS. 1-8, 9A-10I, and 12A-12C.

The memory 520 may store codes and data for operation of the processor 510. The system 500 may be used for mobile phones, MP3 players, navigations, portable multimedia players (PMPs), solid state disks (SSDs), or household appliances.

While the inventive subject matter has been particularly shown and described with reference to exemplary embodiments thereof, it will be understood that various changes in form and details may be made therein without departing from the spirit and scope of the following claims.

What is claimed is:

1. A device comprising:
a semiconductor substrate;
a gate insulation film lining a trench in an active region of the substrate;
a gate electrode pattern recessed in the trench on the gate insulation film and having an upper surface that has a nonuniform height; and
a dielectric pattern disposed on the gate electrode pattern in the trench.

2. The device of claim 1, wherein the upper surface of the gate electrode pattern has a first height at a medial point between sidewalls of the trench and a second height different from the first height at a point more adjacent the sidewalls of the trench.

3. The device of claim 2, wherein the first height is greater than the second height.

4. The device of claim 2, wherein the gate electrode pattern has steps therein.

5. The device of claim 4, wherein the gate electrode pattern comprises a first pattern comprising a first material and conforming to the gate insulation film and a second pattern comprising a second material disposed on and at least partially surrounded by the first pattern.

6. The device of claim 5, wherein the first and second patterns have different resistivities.

7. The device of claim 1, configured such that a depletion region is formed in the substrate at a level above the upper surface of the gate electrode pattern.

8. The device of claim 7, wherein the upper surface of the substrate disposed above the depletion region is electrically connected to a lower electrode of a capacitor.

9. The device of claim 1, wherein the dielectric pattern comprises:
a first dielectric pattern contacting the gate insulation film and the gate electrode pattern; and
a second dielectric pattern disposed on and at least partially surrounded by the first dielectric pattern.

10. The device of claim 9, wherein a permittivity of the first dielectric pattern is different from a permittivity of the second dielectric pattern.

11. The device of claim 1, wherein the gate insulation film is thicker at an upper portion of the trench than at a lower portion of the trench.

12. The device of claim 1, wherein the upper surface of the gate electrode pattern is concave or convex.

13. A device comprising:
a substrate; and
parallel word lines recessed in the substrate, each word line having an upper surface that has a nonuniform height.

14. The device of claim 13, wherein the upper surfaces of the word lines have a first height proximate a medial point thereof and a second height different from the first height proximate a lateral edge thereof.

15. The device of claim 13, wherein the word lines are disposed in respective trenches in the substrate and wherein the device further comprises:
respective gate insulation films lining respective ones of the trenches between the word lines and the substrate; and
respective dielectric patterns disposed on respective ones of the word lines in the trenches.

16. The device of claim 13, wherein the upper surfaces of the word lines have steps therein.

17. The device of claim 16, wherein each of the word lines consists of a single material.

18. The device of claim 16, wherein the word lines are disposed in respective trenches in the substrate and wherein each word line comprises a first pattern comprising a first material and conforming to the sidewalls of one of the trenches and a second pattern comprising a second material disposed on and at least partially surrounded by the first pattern.

19. The device of claim 13, wherein the upper surfaces of the word lines are concave or convex.

20. A device comprising:
a substrate; and
parallel word lines recessed in the substrate, each word line having an upper surface that is concave and/or convex.
